(19) United States
(12) Patent Application Publication
(10) Pub. No.: US 2013/0063672 A1
(43) Pub. Date: Mar. 14, 2013

(54) LIQUID CRYSTAL DISPLAY DEVICE AND MANUFACTURING METHOD THEREOF

(71) Applicants: Dong Guk KIM, Goyang-si (KR); Kazuhiko Tamai, Yokohama-shi (JP)

(72) Inventors: Dong Guk KIM, Goyang-si (KR); Kazuhiko Tamai, Yokohama-shi (JP)

(21) Appl. No.: 13/601,045

(22) Filed: Aug. 31, 2012

(30) Foreign Application Priority Data
Sep. 8, 2011 (KR) 10-2011-0091440

(51) Int. Cl. G02F 1/1335; H01L 33/58; G02F 1/136

(52) U.S. Cl. 349/42; 438/30; 257/E33.053

(57) ABSTRACT

A method of manufacturing an LCD device includes providing a lower substrate including a first substrate on which a thin film transistor, a pixel electrode, and a common electrode are formed, and forming a first light alignment layer on the first substrate that is light aligned in a ultraviolet (UV) irradiation process; providing an upper substrate including a second substrate on which a color filter and a black matrix are formed, and forming a second light alignment layer on the second substrate that is light aligned in the UV irradiation process; providing a light polymerization compound between the lower substrate and upper substrate; and forming an alignment assistant layer between a liquid crystal layer and the first and second light alignment layers by performing a front UV irradiation process on the upper substrate and lower substrate which are coupled to each other with the liquid crystal layer therebetween.

### CROSS-REFERENCE TO RELATED APPLICATIONS

This application claims priority under 35 U.S.C. §119 to Korean Patent Application No. 10-2011-0091440, filed on Sep. 8, 2011, which is hereby incorporated by reference.

### BACKGROUND OF THE INVENTION

1. Field of the Invention

Embodiments of the invention relate to a Liquid Crystal Display (LCD) device and a manufacturing method thereof.

2. Description of the Related Art

Recently, LCD devices have attracted much attention as next generation display devices that consume low amounts of power, are technologically innovative, and are high-value products having good portability.

Such LCD devices include a liquid crystal display panel that displays an image according to a transmittance of light, and a backlight unit that supplies the light to the liquid crystal display panel.

The liquid crystal display panel typically includes a lower substrate that includes a plurality of thin film transistors and pixel electrodes; an upper substrate that faces the lower substrate and includes a plurality of black matrixes and color filters; and a liquid crystal layer that is disposed between the lower substrate and upper substrate.

Moreover, the liquid crystal display panel includes an alignment layer that is formed on a substrate before injecting of liquid crystal, for aligning the liquid crystal in a certain direction. A process of forming the alignment layer is performed by a rubbing scheme that physically contacts a rubbing cloth onto the substrate with alignment materials formed therein.

However, when performing a rubbing process by contacting the rubbing cloth on the alignment layer, elements which are disposed on the substrate, such as thin film transistors, are damaged by static electricity, or the surface of the alignment layer is damaged by the static electricity. Furthermore, when the rubbing cloth is polluted or contaminated, the alignment layer also becomes polluted or contaminated.

To solve such limitations of a related art alignment process, a contactless alignment process is being researched recently. As an example of the contactless alignment process, there is a light alignment scheme using irradiation of light, for example, ultraviolet (UV) light.

FIG. 1 is a view illustrating a light alignment process of a related art. As illustrated in FIG. 1, when a light alignment layer 20 is formed on a substrate 10, organic materials of the light alignment layer 20 are light decomposed in a specific direction by performing a UV irradiation process, and thus, light alignment is performed. Generally, when irradiating UV light in a direction vertical to a direction where liquid crystal molecules 30 are aligned, an alignment direction is set on the light alignment layer 20, in a direction vertical to a direction where the UV light is irradiated.

In this way, when light alignment is performed on the light alignment layer 20 by the UV irradiation process, the liquid crystal molecules 30 are aligned in a specific direction according to a characteristic of the light alignment layer 20 that is aligned in a specific direction by light decomposition.

FIG. 2 is a view illustrating a light alignment principle of the related art. FIG. 3 is a view illustrating limitations in light alignment of the related art.

Referring to FIGS. 2 and 3, when polarized UV light is irradiated on polyimide, which is an organic material, on the light alignment layer 20, light is absorbed, and thus, molecular binding of the polyimide is light decomposed into two maleimides having an alkene structure. R of the maleimide may be bound to one of various diamines.

As described above, when the molecular binding of polyimide is cut by irradiation of UV light, liquid crystal molecules are aligned in a direction vertical to the cut surface of the polyimide. This is because the molecular chain of maleimide is left in a direction vertical to the UV irradiation direction and formed in anisotropy.

As described above, in the light alignment scheme using UV irradiation, the alignment layer is not damaged because the physical contact of the rubbing cloth does not occur, and moreover, additional pollution or contamination due to the rubbing cloth is prevented.

However, as illustrated in FIG. 3, when the rubbing process is performed using the light alignment process, the image-sticking defect of LCD devices arise frequently.

Particularly, when an interface anchoring energy between the alignment layer and liquid crystal layer is weak, the alignment of liquid crystal molecules is changed due to stable alignment, and consequently, light transmittance characteristic is changed, causing the image-sticking defect.

That is, as illustrated in a portion (a) of FIG. 3, when an electric field is supplied to a pixel area, and thus, the pixel area is turned on, liquid crystal molecules are twisted in a certain direction with respect to an initial alignment direction. Twisted angles of the liquid crystal molecules are changed according to a pre-tilt angle of the alignment layer. Subsequently, as illustrated in a portion (b) of FIG. 3, when the electric field is off, the liquid crystal molecules recover to an initial alignment state. At this point, if light alignment is performed, the liquid crystal molecules cannot completely recover to the initial alignment direction due to a weak anchoring energy. This causes the image-sticking defect.

As described above, the light alignment scheme, as a contactless type technique, is superior to a contact alignment scheme that damages the alignment layer, but has an anchoring energy weaker than that of the contact alignment scheme, for example, the rubbing scheme using a rubbing cloth.

### SUMMARY OF THE INVENTION

Embodiments of the invention provide a method of manufacturing an LCD device, which mixes a light polymerization compound with liquid crystal to form an alignment assistant layer between a liquid crystal layer and a light alignment layer, thus reinforcing an anchoring energy between the light alignment layer and liquid crystal molecules.

Embodiments of the invention also provide a method of manufacturing an LCD device, which light aligns a light alignment layer by irradiating UV light, provides a liquid crystal layer by injecting liquid crystal mixed with a light polymerization compound, couples two substrates, and performs a front UV irradiation process, thus enhancing an anchoring energy between the liquid crystal layer and the light alignment layer.

In one embodiment of the invention, a method of manufacturing an LCD device includes: providing a lower substrate including a first substrate on which a thin film transistor, a pixel electrode, and a common electrode are formed, and forming a first light alignment layer on the first substrate that is light aligned in an ultraviolet (UV) irradiation process; providing an upper substrate including a second substrate on which a color filter and a black matrix are formed, and forming a second light alignment layer on the second substrate that is light aligned in the UV irradiation process; providing a light polymerization compound between the lower substrate and upper substrate; and forming an alignment assistant layer between a liquid crystal layer and the first and second light alignment layers by performing a front UV irradiation process on the upper substrate and lower substrate which are coupled to each other with the liquid crystal layer therebetween.

In another embodiment of the invention, an LCD device includes: a lower substrate including: a thin film transistor, a pixel electrode, and a common electrode which are formed on a first substrate; and a first light alignment layer which is light aligned on the thin film transistor, the pixel electrode, and the common electrode; an upper substrate including: a color filter and a black matrix which are formed on a second substrate; and a second light alignment layer which is light aligned on the color filter and the black matrix; a liquid crystal layer including a light polymerization compound between the lower substrate and upper substrate; and an alignment assistant layer formed between the liquid crystal layer and the first and second light alignment layers.

The details of one or more embodiments of the invention are set forth in the accompanying drawings and the description below. Other features will be apparent from the description and drawings, and from the claims.

### BRIEF DESCRIPTION OF THE DRAWINGS

FIG. 1 is a view illustrating a light alignment process of a related art.

FIG. 2 is a view illustrating a light alignment principle of the related art.

FIG. 3 is a view illustrating limitations in light alignment of the related art.

FIGS. 4A to 4E are views illustrating a light alignment process in manufacturing an LCD device according to an embodiment of the invention.

FIGS. 5A and 5B are views illustrating respective examples of a light polymerization compound and photo initiator which are mixed with liquid crystal and included in a liquid crystal layer according to an embodiment of the invention.

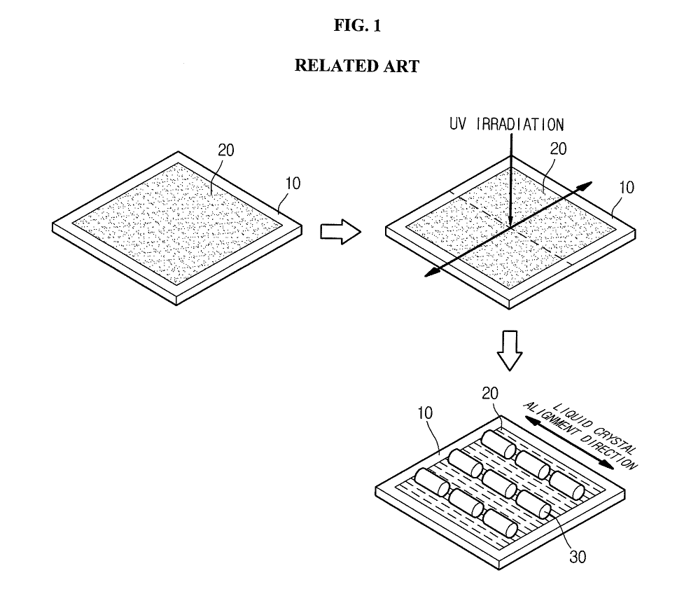

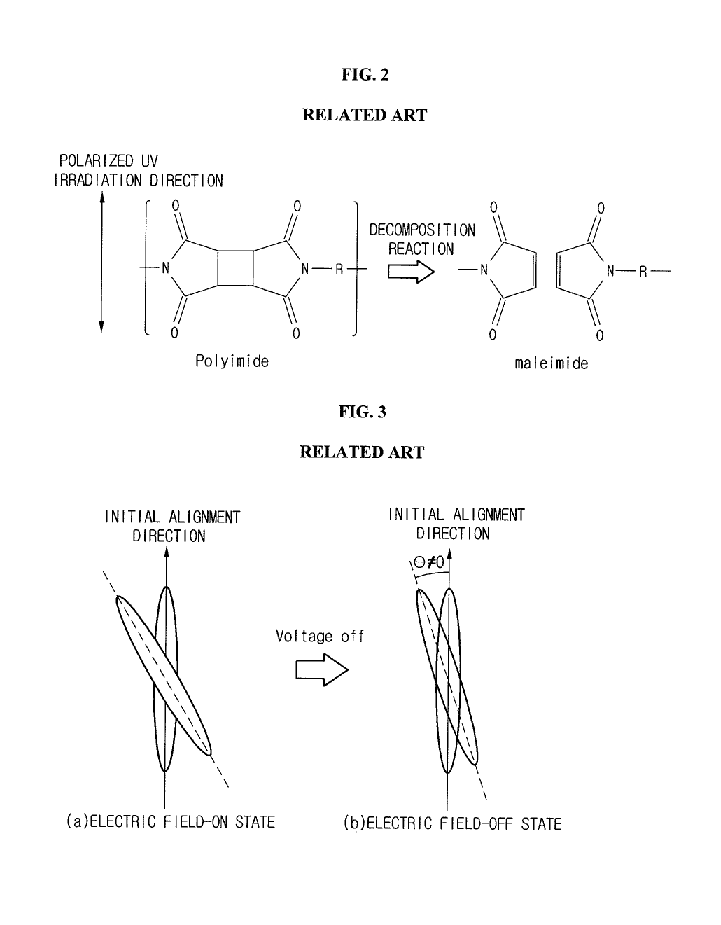

### DETAILED DESCRIPTION OF THE EMBODIMENTS

Hereinafter, embodiments of the invention will be described in detail with reference to the accompanying drawings. Embodiments are provided as examples such that the spirit and scope of the invention may be sufficiently explained to those skilled in the art. The inventive concept may, however, be embodied in different forms and should not be construed as limited only to the embodiments set forth herein. In the drawings, the thicknesses and sizes of elements may be exaggeratedly illustrated for clarity and convenience of description. Like reference numerals refer to like elements throughout.

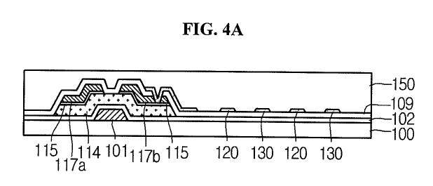

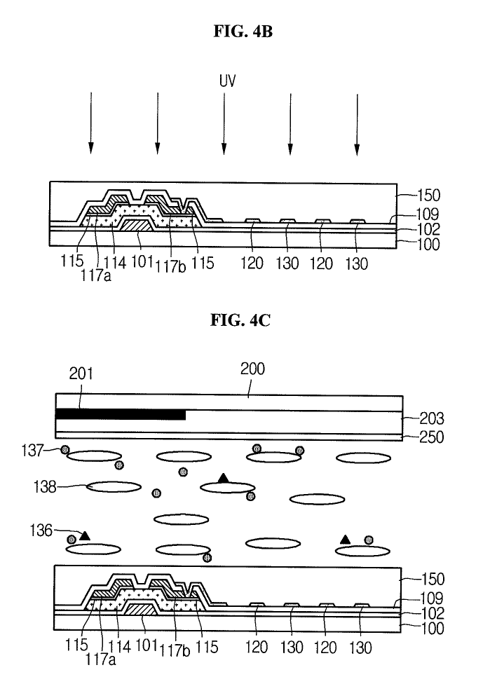

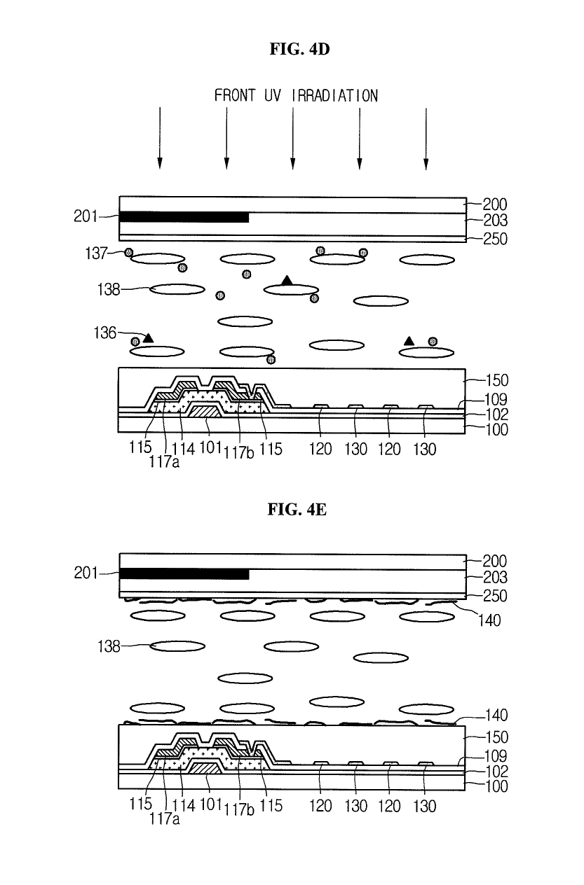

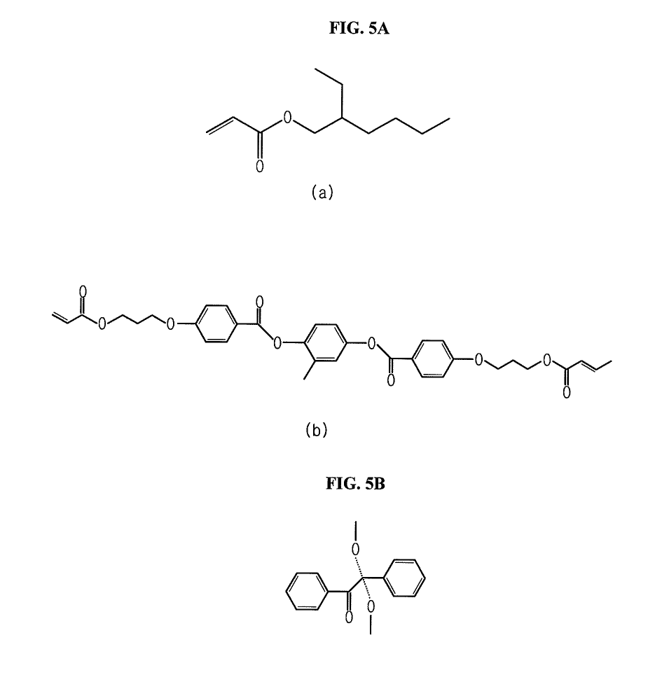

FIGS. 4A to 4E are views illustrating a light alignment process in manufacturing an LCD device according to an embodiment of the invention. FIGS. 5A and 5B are views illustrating respective examples of a light polymerization compound and photo initiator which are mixed with liquid crystal and included in a liquid crystal layer according to an embodiment of the invention.

Referring to FIGS. 4A to 4E, 5A and 5B, a method of manufacturing an LCD device according to an embodiment of the invention provides a lower substrate that includes a Thin Film Transistor (TFT), a gate electrode 101, a pixel electrode 120, and a common electrode 130, on a first substrate 100 formed of a transparent insulation material. Herein, the thin film transistor includes the gate electrode 101, a gate insulation layer 102, a channel layer 114, an ohmic contact layer 115, a source electrode 117a, and a drain electrode 117b. The pixel electrode 120 is electrically connected to the drain electrode 117b of the thin film transistor, and formed on a passivation layer 109 in a pixel area.

In the embodiment of the invention, a structure in which the pixel electrode 120 and common electrode 130 are alternately disposed is described as an example, but the embodiments of the invention are not limited thereto. The method according to an embodiment of the invention may be identically applied to an In Panel Switching (IPS) mode where the pixel electrode 120 or common electrode 130 is formed on the passivation layer 109 in a slit type configuration, and formed under the passivation layer 109 in a slit or plate type configuration. That is, the pixel electrode 120 and common electrode 130 may be disposed vertically about the passivation layer 109.

Moreover, the method according to an embodiment of the invention may be identically applied to a Twisted Nematic (TN) mode or a Vertically Alignment (VA) mode in which a plurality of pixel electrodes are formed on a lower substrate with thin film transistors formed thereon, and a plurality of common electrodes are formed on an upper substrate, on which a plurality of color filters are formed, in correspondence with the respective pixel electrodes.

As described above, when the lower substrate including the thin film transistor, pixel electrode 120, and the common electrode 130 are completed on the first substrate 100, a first light alignment layer 150 is formed over the first substrate 100.

Subsequently, as illustrated in FIG. 4B, a first light alignment layer 150 is light aligned by a UV irradiation process. The first light alignment layer 150 may be formed of a light alignment material, for example, an organic material that is light decomposed through light irradiation.

Once the first light alignment layer 150 is formed on the first substrate 100, a sintering process and a hardening process may be performed sequentially, and the first light alignment layer 150 may be light aligned by the UV irradiation process. Subsequently, a cleaning process and a thermal treatment process (i.e., post bake) may be performed.

When the UV irradiation process is completed, as illustrated in FIG. 4C, the lower substrate is coupled to an upper substrate with a color filter layer 203 formed thereon, and a liquid crystal layer is formed between the lower substrate and upper substrate. The upper substrate may include a black matrix 201, and the color filter layer 203 that is formed on a second substrate 200 of a transparent insulation material and which includes a plurality of red (R) color filters, green (G) color filters, and blue (B) color filters. An overcoat layer for planarization may be formed on the upper substrate.

A second light alignment layer 250 is formed on the color filter layer 203. The second alignment layer 250 may be formed of the same material as that of the first light alignment layer 150, and the second light alignment layer 250 is light aligned by the UV irradiation process.

The liquid crystal layer may be formed by a liquid crystal injection process after the upper substrate and lower substrate are coupled. Alternatively, the liquid crystal may be dispensed onto the upper substrate or lower substrate, and then the liquid crystal layer may be formed by a liquid crystal dispensing process of coupling the upper substrate and the lower substrate.

The liquid crystal layer according to an embodiment of the invention includes a liquid crystal 138, a light polymerization compound 137 and a photoinitiator 136.

The light polymerization compound 137 may be selected from a material that is referred to as a monomer or an oligomer. For example, the light polymerization compound 137 may use polymerization compounds such as an acrylate group including acrylic acid ester and methacrylic acid ester, a methacrylate group, an epoxy group, a vinyl group, or an allyl group. A molecular formula of a material usable as the light polymerization compound 137 is illustrated in FIG. 5A.

Moreover, the photoinitiator 136 may have an acrylic component, or use a-hydroxy ketone, a-amino ketone, and Benzil Dimethyl Ketal (BDK). FIG. 5B illustrates a structural formula of the photoinitiator 136 as an example.

Content of the light polymerization compound 137 is about 0.1 wt % to about 3 wt % in the liquid crystal layer, and content of the photoinitiator 136 is about 0.05 wt % to about 0.5 wt % in the liquid crystal layer.

As described above, once the liquid crystal layer including the light polymerization compound 137 is formed, as illustrated in FIG. 4D, another UV irradiation process (or a front UV irradiation process) is performed over the coupled upper and lower substrates.

The UV irradiation process may be respectively performed in an upper portion and lower portion of the coupled upper and lower substrates. The UV irradiation process is not a process of aligning light on a light alignment layer but is a process that thermally hardens the light polymerization compound 137 to form a polymer chain layer at an interface between the liquid crystal layer and light alignment layer.

The UV irradiation process may transfer about 70% to about 80% of UV light, irradiated from outside a substrate, to the liquid crystal layer. For example, when the amount of the irradiated UV light is about 51 mW/cm², the amount of UV light transferred to the liquid crystal layer is about 35 mW/cm² to about 45 mW/cm². The irradiated light may have various wavelengths, but a light hardening reaction is induced by irradiating UV light having a wavelength of about 365 nm.

Moreover, a dipole moment of the light polymerization compound 137 may be less than or equal to about 5 debye, and the liquid crystal including the light polymerization compound 137 may be disposed between the substrates by a liquid crystal injection process or a liquid crystal dispensing process.

In this way, when a heat hardening process is performed using the UV irradiation process, the light polymerization compound 137 included in the liquid crystal layer forms a polymer chain at an interface between the liquid crystal layer, and the first and second light alignment layers 150 and 250, and an alignment assistant layer 140 including the polymer chain is formed.

The light polymerization compound 137 forms the polymer chain through the light hardening reaction, and thus, the alignment assistant layer 140 is formed. The alignment assistant layer 140 reinforces a weak anchoring energy due to the light alignment process, at interfaces between the liquid crystal layer, and the first and second light alignment layers 150 and 250.

When the alignment assistant layer 140 including the polymer chain is formed between the liquid crystal layer, and the first and second light alignment layers 150 and 250, a thermal treatment process may be additionally performed at a temperature range from 80° C. to 150° C.

In embodiments of the invention, the alignment assistant layer 140 may be formed of a collection of polymer chains that are formed on the first and second light alignment layers 150 and 250. The polymer chains may be formed into a fiber like configuration, a plate like configuration or both. The collection of polymer chains may be mesh-like or may form dense layers to form the alignment assistant layer. The polymer chains may be discontinuous.

Moreover, the method according to an embodiment of the invention may be applied to an instance where light alignment is made at 10 degrees or less in pre-tilt angles of the liquid crystal molecules of the liquid crystal layer even when light is aligned by the light alignment process.

As described above, in order to solve or address a limitation in the contactless light alignment scheme using UV irradiation having a weak anchoring energy, the method according to an embodiment of the invention forms the alignment assistant layer that includes the polymer chain between the liquid crystal layer and light alignment layer, and thus reinforces the anchoring energy, thereby reducing the image-sticking defect.

The method of manufacturing the LCD device according to the embodiments of the invention mixes the light polymerization compound with the liquid crystal to form the alignment assistant layer between the liquid crystal layer and light alignment layer, thus reinforcing the anchoring energy between the light alignment layer and liquid crystal molecules.

The method of manufacturing the LCD device according to the embodiments of the invention aligns light by irradiating UV light, forms the liquid crystal layer by injecting the liquid crystal mixed with the light polymerization compound, couples the substrates, and performs the front UV irradiation process, thus enhancing the anchoring energy between the liquid crystal layer and light alignment layer.

Although embodiments of the invention have been described with reference to a number of illustrative embodiments of the invention thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a Liquid Crystal Display (LCD) device, the method comprising:
providing a lower substrate comprising a first substrate on which a thin film transistor, a pixel electrode, and a common electrode are formed, and forming a first light alignment layer on the first substrate that is light aligned in an ultraviolet (UV) irradiation process;
providing an upper substrate comprising a second substrate on which a color filter and a black matrix are formed, and forming a second light alignment layer on the second substrate that is light aligned in the UV irradiation process;
providing a light polymerization compound between the lower substrate and upper substrate; and
forming an alignment assistant layer between a liquid crystal layer and the first and second light alignment layers by performing a front UV irradiation process on the upper substrate and lower substrate which are coupled to each other with the liquid crystal layer therebetween.

2. The method according to claim 1, wherein the pixel electrode and common electrode are formed alternatingly on a passivation layer.

3. The method according to claim 1, wherein the light polymerization compound is one of a monomer-based material and an oligomer-based material.

4. The method according to claim 3, wherein the light polymerization compound includes one selected from among an acrylate group comprising acrylic acid ester and methacrylic acid ester, a methacrylate group, an epoxy group, a vinyl group, and an allyl group.

5. The method according to claim 1, wherein a content of the light polymerization compound is about 0.1 wt % to about 3 wt % in the liquid crystal layer.

6. The method according to claim 1, wherein the liquid crystal layer further comprises a photoinitiator which is formed of one of acryl, a-hydroxy ketone, and a-amino ketone.

7. The method according to claim 6, wherein a content of the photoinitiator is about 0.05 wt % to about 0.5 wt % in the liquid crystal layer.

8. The method according to claim 1, wherein the alignment assistant layer comprises a polymer chain which is formed by thermally hardening the light polymerization compound in the front UV irradiation process.

9. The method according to claim 8, wherein the polymer chain is formed at an interface between the liquid crystal layer, and the first and second light alignment layers, thereby reinforcing an anchoring energy between liquid crystal layer, and the first and second light alignment layers.

10. The method according to claim 8, wherein the first and second light alignment layers are light aligned at 10 degrees or less in pre-tilt angles of liquid crystal molecules of the liquid crystal layer.

11. A Liquid Crystal Display (LCD) device comprising:
a lower substrate comprising a thin film transistor, a pixel electrode, and a common electrode which are formed on a first substrate; and a first light alignment layer which is light aligned on the thin film transistor, the pixel electrode, and the common electrode;
an upper substrate comprising a color filter and a black matrix which are formed on a second substrate; and a second light alignment layer which is light aligned on the color filter and the black matrix;
a liquid crystal layer comprising a light polymerization compound between the lower substrate and upper substrate; and
an alignment assistant layer formed between the liquid crystal layer and the first and second light alignment layers.

12. The LCD device according to claim 11, wherein the pixel electrode and the common electrode are formed alternatingly on a passivation layer.

13. The LCD device according to claim 11, wherein the light polymerization compound is one of a monomer-based material and an oligomer-based material.

14. The LCD device according to claim 13, wherein the light polymerization compound includes one of an acrylate group comprising acrylic acid ester and methacrylic acid ester, a methacrylate group, an epoxy group, a vinyl group, and an allyl group.

15. The LCD device according to claim 11, wherein a content of the light polymerization compound is about 0.1 wt % to about 3 wt % in the liquid crystal layer.

16. The LCD device according to claim 11, wherein the liquid crystal layer further comprises a photoinitiator which is formed of one of acryl, a-hydroxy ketone, and a-amino ketone.

17. The LCD device according to claim 16, wherein a content of the photoinitiator is about 0.05 wt % to about 0.5 wt % in the liquid crystal layer.

18. The LCD device according to claim 11, wherein the alignment assistant layer comprises a polymer chain which is formed by thermally hardening the light polymerization compound in a UV irradiation process.

19. The LCD device according to claim 11, wherein the first and second light alignment layers are light aligned at 10 degrees or less in pre-tilt angles of liquid crystal molecules of the liquid crystal layer.
